(19) United States
(12) Patent Application Publication
(10) Pub. No.: US 2004/0170923 A1
(43) Pub. Date: Sep. 2, 2004

(54) Colored stereolithographic resins

(75) Inventors: Alfred Steinmann, Praroman (CH); Bettina Steinmann, Praroman (CH); Manfred Hofmann, Marly (CH)

Correspondence Address: 3D Systems, Inc., 26081 Avenue Hall, Valencia, CA, 91355, US

(73) Assignee: 3D Systems, Inc.

(21) Appl. No.: 10/376,546

(22) Filed: Feb. 27, 2003

(51) Int. Cl. G03F 7/028

(52) U.S. Cl. 430/280.1; 430/285.1; 430/269; 522/78; 522/80; 522/74; 264/401

(57) ABSTRACT

A liquid colored radiation-curable composition that comprises:

(A) at least one cationically polymerizing organic substance;

(B) at least one free-radical polymerizing organic substance;

(C) at least one cationic polymerization initiator;

(D) at least one free-radical polymerization initiator; and

(E) an effective color-imparting amount of at least one soluble dye compound selected from the group consisting of diarylmethane and triarylmethane dyes, rhodamine dyes, azo dyes, thiazole dyes, anthraquinone dyes and safranine dyes; said liquid colored radiation-curable composition having substantially the same photospeed as the composition without dye component (E) and the liquid dye compound does not bleach out during radiation exposure.

### BACKGROUND OF THE INVENTION

1. Field of the Invention

The present invention relates to selected liquid, colored radiation-curable compositions which are particularly suitable for the production of colored three-dimensional articles by stereolithography as well as a process for the production of colored cured articles and the cured three-dimensional shaped colored article themselves. In particular, this invention relates to a liquid, radiation-curable resin compositions from which cured three-dimensional shaped articles having excellent color properties.

2. Brief Description of Art

The production of three-dimensional articles of complex shape by means of stereolithography has been known for a relatively long time. In this technique the desired shaped article is built up from a liquid, radiation-curable composition with the aid of a recurring, alternating sequence of two steps (a) and (b); in step (a), a layer of the liquid, radiation-curable composition, one boundary of which is the surface of the composition, is cured with the aid of appropriate radiation, generally radiation produced by a preferably computer-controlled laser source, within a surface region which corresponds to the desired cross-sectional area of the shaped article to be formed, at the height of this layer, and in step (b) the cured layer is covered with a new layer of the liquid, radiation-curable composition, and the sequence of steps (a) and (b) is repeated until a so-called green model of the desired three-dimensional shape is finished. This green model is, in general, not yet fully cured and must therefore, normally, be subjected to post-curing.

The mechanical strength of the green model (modulus of elasticity, fracture strength), also referred to as green strength, constitutes an important property of the green model and is determined essentially by the nature of the stereolithographic resin (SL) composition employed. Other important properties of a stereolithographic resin composition include a high sensitivity for the radiation employed in the course of curing and a minimum curl factor, permitting high shape definition of the green model. In addition, for example, the precured material layers should be readily wettable by the liquid stereolithographic resin composition, and of course not only the green model but also the ultimately cured shaped article should have optimum mechanical properties.

In order to achieve the desired balance of properties, different types of stereolithographic resin systems have been proposed. For example, radical-curable stereolithographic resin systems have been proposed. These systems generally consist of one or more (meth)acrylate compounds (or other free-radical polymerizable organic compounds) along with a free-radical photoinitiator for radical generation. U.S. Pat. No. 5,418,112 describes one such radical-curable system.

Another type of resin composition suitable for this purpose is a dual-type stereolithographic resin system that comprises (i) epoxy resins or other types of cationic polymerizable compounds; (ii) cationic polymerization initiator; (iii) acrylate resins or other types of free radical polymerizable compounds; and (iv) a free radical polymerization initiator. Examples of such dual or hybrid systems are described in U.S. Pat. Nos. 5,434,196, 5,972,563; 6,100,007 and 6,287,748.

Separately, there have been four (4) general ways to produce a colored stereolithographic resin product. The first way was to disperse color pigments into the uncured resin formulation and then cure that pigment-laden formulation. There are several disadvantages associated with the use of pigment materials in stereolithographic resin production. A relatively high concentration of pigment is needed in the uncured resin formulation for a strong coloration and special blending equipment and/or additives are required to produce uniform and stable pigment dispersions. Undesirable absorption and light scattering may occur during the SL laser exposure because of the pigment particles. Also, unwanted sedimentation of the pigment particles can occur in the SL vat before or during the laser exposure causing a color differential in the layers of the cured product. Accordingly, because of these reasons, colored pigment use in stereolithographic resins has not been favored for widespread commercial applications.

The second prior art method of coloring an SL resin has been to apply a dye solution to the surface of cured SL resin after laser exposure. See European Patent Application No. 0250121 A2 (e.g. column 22, lines 16-41) as an example of this technique. This dyeing technique requires an additional processing step and may lead to undesirable swelling of the cured part by absorption of the liquid colorant into the part. Also, the color is only at the surface of the cured part. Wear or scratching of the cured part may remove the color. Accordingly, this coloring method is also not commercially acceptable.

The third prior method of coloring an SL resin product entailed surface coloring the cured part with a colored lacquer. Again, this surface coating with a lacquer requires an additional processing step that raises the cost of each part and the color is only at the surface of the cured part. Furthermore, the lacquer may undesirably fill small or fine holes or textures in the part, thus making them unuseful or unattractive.

The fourth prior art method of coloring SL resins is to add to the uncured SL resin formulation a material that changes color upon irradiation. One such material is SOMOS 7620, an epoxy based stereolithography resin available from DSM Desotech, that becomes dark gray upon laser irradiation. Such color change materials are not acceptable for certain applications. Also, the color change reaction of these materials depends on the irradiation dose and consumes protons that are normally needed for the polymerization of the SL base resins (these protons are formed by the cationic photoinitiator upon irradiation). This makes curing much slower and the physical properties of the cured resin may be adversely affected.

Again, this method like the other three, has not gained widespread acceptance for making cured colored SL products because of these problems.

Accordingly, there is a need for an improved liquid, colored stereolithographic resin that does not have these prior art problems. The present invention offers an answer to that need.

### BRIEF SUMMARY OF THE INVENTION

Therefore, one aspect of the present invention is directed to a liquid colored radiation-curable composition useful for the production of three dimensional articles by stereolithography comprising a substantially homogeneous admixture of (1) liquid radical-curable or dual-type stereolithographic resin system and (2) an effective color-imparting amount of at least one soluble dye compound selected from the group consisting of di- and triarylmethane dyes, rhodamine dyes, azo dyes, thiazole dyes, anthraquinone dyes and safranine dyes, said colored radiation-curable composition having substantially the same photospeed as the uncolored resin system and the liquid dye compound does not bleach out during radiation exposure.

Another aspect of the present invention is directed to a liquid radiation-curable composition useful for the production of three dimensional articles by stereolithography that comprises a substantially homogeneous admixture of:

(A) at least one cationically polymerizing organic substance;

(B) at least one free-radical polymerizing organic substance;

(C) at least one cationic polymerization initiator;

(D) at least one free-radical polymerization initiator; and

(E) an effective color-imparting amount of at least one soluble dye compound selected from the group consisting of di-and triarylmethane dyes, rhodamine dyes, azo dyes, thiazole dyes, anthraquinone dyes and safranine dyes, said colored radiation-curable composition having substantially the same photospeed as the uncolored resin system and the soluble dye compound does not bleach out during radiation exposure.

Another aspect of the present invention is directed to a process for forming a three-dimensional article, said process comprising the steps:

(1) coating a thin layer of a radiation-curable composition as described above onto a surface;

(2) exposing said thin layer imagewise to actinic radiation to form an imaged cross-section, wherein the radiation is of sufficient intensity to cause substantial curing of the thin layer in the exposed areas;

(3) coating a thin layer of the composition onto the previously exposed imaged cross-section;

(4) exposing said thin layer from step (3) imagewise to actinic radiation to form an additional imaged cross-section, wherein the radiation is of sufficient intensity to cause substantial curing of the thin layer in the exposed areas and to cause adhesion to the previously exposed imaged cross-section;

(5) repeating steps (3) and (4) a sufficient number of times in order to build up the three-dimensional article;

wherein the radiation-curable composition is that which is described above.

Still another aspect of the present invention is directed to three-dimensional articles made by the above process using the above-noted radiation-curable compositions.

The colored stereolithographic resin compositions of the present invention have several advantages over the prior art methods for achieving colored stereolithographic resin products. The colored parts may have excellent lightfastness that make the cured resins particularly visible. This is especially important for stereolithographic resin products in the jewelry industry, which require good color contrast in thin layers and with the transparent silicone molds from which the SL resin must be removed along a parting line, or in the electronic or watch industries which work with very small parts that need strong colorations to improve magnified viewing of the parts.

Another advantage of the present invention is that the inclusion of these selected soluble dye compounds does not result in undesirable viscosity changes in the uncured resin. Furthermore, the liquid, colored radiation-curable compositions of the present invention do not experience a dropoff in photospeed properties because of the inclusion of these specific dyes. Since the dyes are soluble in the liquid SL resins, there is no unwanted light scattering, sedimentation or line broadening caused by their inclusion. Those dyes with amino groups in their molecules may also act as stabilizers to extend the shelf life of the liquid dual-type SL resins having cationically and free-radical polymerizing substances. Dyes that have primary or secondary amino groups, hydroxyl groups, carboxyl groups or (meth)acrylate groups in the molecule react with the functional groups of the resin composition and are covalently bound to the resulting network upon irradiation. These selected dyes are not extracted by solvents after curing and do not bleach out upon irradiation. Also they are effective at relatively low concentrations, and do not require a second dying step after curing and have very good long term stability in air and exposure to UV light.

### DETAILED DESCRIPTION OF THE INVENTION

The term “(meth)acrylate” as used in the present specification and claims refers to both acrylates and methacrylates.

The term “liquid” as used in the present specification and claims is to be equated with “liquid at room temperature” which is, in general, a temperature range between 5° C. and 30° C.

The novel compositions herein contain, in the broadest sense, a mixture of at least one liquid radical-curable or dual-type stereolithographic resin system with an effective amount of one or more of the above-noted soluble dye compounds. Preferably, the resin system is a dual-type SL system that is a mixture of at least one cationically polymerizable organic substance; at least one selected free-radical polymerizing organic substance; at least one cationic polymerization initiator and at least one free-radical polymerization initiator; and at least one hydroxyl-functional compound. These SL compositions may further optionally contain other additives. If the SL resin system is a dual-type resin system, the preferred components are as follows:

(A) Cationically Polymerizable Organic Substances

The cationically polymerizable compound may expeditiously be an aliphatic, alicyclic or aromatic polyglycidyl compound or cycloaliphatic polyepoxide or epoxy cresol novolac or epoxy phenol novolac compound and which on average possess more than one epoxide group (oxirane ring) in the molecule. Such resins may have an aliphatic, aromatic, cycloaliphatic, araliphatic or heterocyclic structure; they contain epoxide groups as side groups or these groups form part of an alicyclic or heterocyclic ring system. Epoxy resins of these types are known in general terms and some are commercially available.

Examples of such suitable epoxy resins are disclosed in U.S. Pat. No. 6,100,007.

Also conceivable is the use of liquid prereacted adducts of epoxy resins, such as those mentioned above, with hardeners for epoxy resins.

It is of course also possible to use liquid mixtures of liquid or solid epoxy resins in the novel compositions.

Examples of cationically polymerizable organic substances other than epoxy resin compounds include oxetane compounds, such as trimethylene oxide; 3,3-dimethyloxetane and 3,3-dichloromethyloxetane; 3-ethyl-3-phenoxymethyloxetane; oxolane compounds, such as tetrahydrofuran and 2,3-dimethyl-tetrahydrofuran; cyclic acetal compounds, such as trioxane, 1,3-dioxolane and 1,3,6-trioxan cyclooctane; cyclic lactone compounds, such as β-propiolactone and ε-caprolactone; cyclic carbonates, such as propylene carbonate and 1,3,dioxolane-2-carbonate; thiirane compounds, such as ethylene sulfide, 1,2-propylene sulfide and thioepichlorohydrin; and thiotane compounds, such as 1,3-propylene sulfide and 3,3-dimethylthiothane.

Examples of such other cationically polymerizable compounds are also disclosed in U.S. Pat. No. 6,100,007.

Preferably, the cationically polymerizable compounds of the present invention constitute about 30% to 80% by weight of the radiation-curable composition.

One particularly preferred embodiment of the present invention contains two types of cationically polymerizing organic substances. One type is an alicylic epoxide having at least one to two epoxy groups. The other type is at least one difunctional or higher functional-glycidylether of a polyhydric compound.

(1) Alicyclic Epoxides having at Least Two Epoxy Groups

The cationically polymerizing alicyclic epoxides having at least two epoxy groups include any cationically curable liquid or solid compound that may be an alicyclic polyglycidyl compound or cycloaliphatic polyepoxide which on average possesses two or more epoxide groups (oxirane rings) in the molecule. Such resins may have a cycloaliphatic ring structure that contain the epoxide groups as side groups or the epoxide groups form part of the alicyclic ring structure. Such resins of these types are known in general terms and some are commercially available.

Examples of compounds in which the epoxide groups form part of an alicyclic ring system include bis(2,3-epoxycyclopentyl) ether; 2,3-epoxycyclopentyl glycidyl ether; 1,2-bis(2,3-epoxycyclopentyloxy)ethane; 3,4-epoxycyclohexylmethyl-3′,4′-epoxycyclohexanecarboxylate; 3,4-epoxy-6-methyl-cyclohexylmethyl 3,4-epoxy-6-methylcyclohexanecarboxylate; di(3,4-epoxycyclohexylmethyl) hexanedioate; di(3,4-epoxy-6-methylcyclohexylmethyl) hexanedioate; ethylenebis(3,4-epoxycyclohexane-carboxylate; ethanediol di(3,4-epoxycyclohexylmethyl) ether; vinylcyclohexene dioxide; dicyclopentadiene diepoxide; and 2-(3,4-epoxycyclohexyl-5,5-spiro-3,4-epoxy)cyclohexane-1,3-dioxane.

The preferred alicyclic epoxide is 3,4-epoxycyclohexylmethyl-3′,4′-epoxy-cyclohexanecarboxylate which is available as Cyracure UVR 6110.

For this particularly preferred embodiment, these alicyclic epoxides preferably constitute from about 50% to about 90% by weight, more preferably from about 60% to 85% by weight of the total cationic polymerizing organic substances.

(2) Difunctional or Higher Functional Glycidylethers of a Polyhydric Compound

The cationically polymerizing difunctional or higher functionality glycidylethers of a polyhydric compound are obtainable by reacting a compound having at least two free alcoholic hydroxyl groups with a suitably substituted epichlorohydrin under alkaline conditions or in the presence of an acidic catalyst followed by alkali treatment. Ethers of this type may be derived from primary or secondary alcohols, such as ethylene glycol; propane-1,2-diol or poly (oxy propylene) glycols; propane-1,3-diol; butane-1,4-diol; poly (oxytetramethylene) glycols; pentane-1,5-diols; hexane-1,6-diol; hexane-2,4-,6-triol; glycerol; 1,1,1-trimethylol propane; bistrimethylol propane; pentaerythritol; sorbitol and the like when reacted with polyepichlorohydrins. Such resins of these types are known in general terms and are commercially available.

The most preferred difunctional or higher functional glycidylether is trimethylol propane triglycidylether which is available as Araldite DY-T.

For this particular preferred embodiment, these difunctional or higher functional glycidylether preferably constitute from about 10% to about 50% by weight, more preferably about 15% to about 40% by weight of the total cationic polymerizing organic substances.

(B) Free-Radical Polymerizing Organic Substance

The free radically curable component preferably comprises at least one solid or liquid poly(meth)acrylate, for example, di-, tri-, tetra- or pentafunctional monomeric or oligomeric aliphatic, cycloaliphatic or aromatic acrylates or methacrylates. The compounds preferably have a molecular weight of from 200 to 500.

Examples of suitable aliphatic poly(meth)acrylates having more than two (meth)acrylate groups in their molecules are the triacrylates and trimethacrylates of hexane-2,4,6-triol; glycerol or 1,1,1-trimethylolpropane; ethoxylated or propoxylated glycerol or 1,1,1-trimethylolpropane; and the hydroxyl-containing tri(meth)acrylates which are obtained by reacting triepoxide compounds, for example the triglycidyl ethers of said triols, with (meth)acrylic acid. It is also possible to use, for example, pentaerythritol tetraacrylate, bistrimethylolpropane tetraacrylate, pentaerythritol monohydroxytriacrylate or -methacrylate, or dipentaerythritol monohydroxypentaacrylate or -methacrylate.

It is additionally possible, for example, to use polyfunctional urethane acrylates or urethane methacrylates. These urethane (meth)acrylates are known to the person skilled in the art and can be prepared in a known manner by, for example, reacting a hydroxyl-terminated polyurethane with acrylic acid or methacrylic acid, or by reacting an isocyanate-terminated prepolymer with hydroxyalkyl (meth)acrylates to give the urethane (meth)acrylate.

Preferably, these free radical polymerizable compounds constitute about 1% to about 20% of the radiation-curable composition.

One particularly preferred class of free radical polymerizable compounds are aromatic di(meth) acrylate compounds. Optionally, this particular preferred embodiment also contains a trifunctional or higher functionality (meth) acrylate compound.

(1) Aromatic Di(meth)acrylate Compounds

The aromatic di(meth)acrylate compounds include difunctional aromatic acrylates or difunctional aromatic methacrylates. Suitable examples of these di(meth)acrylate compounds include di(meth)acrylates of aromatic diols such as hydroquinone; 4,4′-dihydroxybis-phenyl; bisphenol A; bisphenol F; bisphenol S; ethoxylated or propoxylated bisphenol A; ethoxylated or propoxylated bisphenol F or ethoxylated or propoxylated bisphenol S. Di(meth)acrylates of this kind are known and some are commercially available.

The most preferred aromatic difunctional (meth)acrylate is bisphenol A diglycidylether diacrylate which is available as Ebecryl 3700.

These aromatic difunctional (meth)acrylates preferably constitute from 0 to about 20% by weight, more preferably, from about 3% to about 10% by weight of the total liquid radiation-curable composition.

(2) Optional Trifunctional or Higher Functionality (Meth) acrylate Compounds

The optional trifunctional or higher functionality meth(acrylates) are preferably tri-, tetra- or pentafunctional monomeric or oligomeric aliphatic, cycloaliphatic or aromatic acrylates or methacrylates. Such compounds preferably have a molecular weight of from about 200 to about 500.

Examples of suitable aliphatic tri-, tetra- and pentafunctional (meth)acrylates are the triacrylates and trimethacrylates of hexane-2,4,6-triol; glycerol or 1,1,1-trimethylolpropane; ethoxylated or propoxylated glycerol or 1,1,1-trimethylolpropane; and the hydroxyl-containing tri(meth)acrylates which are obtained by reacting triepoxide compounds, for example the triglycidyl ethers of said triols, with (meth)acrylic acid. It is also possible to use, for example, pentaerythritol tetraacrylate, bistrimethylolpropane tetraacrylate, pentaerythritol monohydroxytriacrylate or -methacrylate, or dipentaerythritol monohydroxypentaacrylate or -methacrylate.

Examples of suitable aromatic tri(meth)acrylates are the reaction products of triglycidyl ethers of trihydroxy benzene and phenol or cresol novolaks containing three hydroxyl groups, with (meth)acrylic acid.

These higher functional (meth) acrylates are known compounds and some are commercially available, for example from the SARTOMER Company under product designations such as SR295, SR350, SR351, SR367, SR399, SR444, SR454 or SR9041.

The most preferred higher functional (meth)acrylate compound is SARTOMER SR399, which is dipentaerythritol monohydroxy-pentaacrylate.

These optional higher functional (meth)acrylates, if used, preferably constitute about 1% to about 20% by weight, more preferably, from about 5% to about 15% by weight of the total liquid radiation-curable composition.

(C) Cationic Polymerization Initiators

In the compositions according to the invention, any type of photoinitiator that, upon exposure to actinic radiation, forms cations that initiate the polymerization reaction of the epoxy material(s) can be used. There are a large number of known and technically proven cationic photoinitiators for epoxy resins that are suitable. They include, for example, onium salts with anions of weak nucleophilicity. Examples are halonium salts, iodosyl salts or sulfonium salts, such as described in published European patent application EP 153904, sulfoxonium salts, such as described, for example, in published European patent applications EP 35969, 44274, 54509, and 164314, or diazonium salts, such as described, for example, in U.S. Pat. Nos. 3,708,296 and 5,002,856. Other cationic photoinitiators are metallocene salts, such as described, for example, in published European applications EP 94914 and 94915. Other preferred cationic photoinitiators are mentioned in U.S. Pat. No. 5,972,563 (Steinmann et al.); U.S. Pat. No. 6,100,007 (Pang et al.) and U.S. Pat. No. 6,136,497 (Melisaris et al.).

More preferred commercial cationic photoinitiators are UVI-6974, UVI-6976, UVI-6990 (available commercially from Union Carbide Corp.), CD-1010, CD-1011, CD-1012 (available commercially from Sartomer Corp.), Adekaoptomer SP-150, SP-151, SP-170, SP-171 (available commercially from Asahi Denka Kogyo Co., Ltd.), Irgacure 261 (available commercially from Ciba Specialty Chemicals Corp.), CI-2481, CI-2624, CI-2639, CI-2064 (available commercially from Nippon Soda Co., Ltd.), and DTS-102, DTS-103, NAT-103, NDS-103, TPS-103, MDS-103, MPI-103, BBI-103 (available commercially from Midori Chemical Co., Ltd.). Most preferred are UVI-6974, UVI 6976, CD-010, UVI-6970, Adekaoptomer SP-170, SP-171, CD-1012, and MPI-103. The above mentioned cationic photoinitiators can be used either individually or in combination of two or more.

The most preferred cationic photoinitiator is a triarylsulfonium hexafluoroantemonate such as UVI-6974 (from Union Carbide).

The cationic photoinitiators may constitute from about 0.01% to about 10 % by weight, more preferably, from about 0.02% to about 5 by weight, of the total radiation-curable composition.

(D) Free Radical Polymerization Initiators

In the compositions according to the invention, any type of photoinitiator that forms free radicals when the appropriate irradiation takes place can be used. Typical compounds of known photoinitiators are benzoins, such as benzoin, benzoin ethers, such as benzoin methyl ether, benzoin ethyl ether, and benzoin isopropyl ether, benzoin phenyl ether, and benzoin acetate, acetophenones, such as acetophenone, 2,2-dimethoxyacetophenone, 4-(phenylthio)acetophenone, and 1,1-dichloroacetophenone, benzil, benzil ketals, such as benzil dimethyl ketal, and benzil diethyl ketal, anthraquinones, such as 2-methylanthraquinone, 2-ethylanthraquinone, 2-tert-butylanthraquinone, 1-chloroanthraquinone, and 2-amylanthraquinone, also triphenylphosphine, benzoylphosphine oxides, such as, for example, 2,4,6-trimethylbenzoyldiphenylphosphine oxide (Lucirin® TPO), benzophenones, such as benzophenone, and 4,4′-bis(N,N′-dimethylamino)benzophenone, thioxanthones and xanthones, acridine derivatives, phenazene derivatives, quinoxaline derivatives or 1-phenyl-1,2-propanedione-2-O-benzoyloxime, 1-aminophenyl ketones or 1-hydroxyphenyl ketones, such as 1-hydroxycyclohexyl phenyl ketone, phenyl (1-hydroxyisopropyl)ketone and 4-isopropylphenyl(1-hydroxyisopropyl)ketone, or triazine compounds, for example, 4′ methyl thiophenyl-1-di(trichloromethyl)-3,5 S-triazine, S-triazine-2-(stylbene)-4,6-bis-trichloromethyl, and paramethoxy stiryl triazine, all of which are known compounds.

Especially suitable free-radical photoinitiators, which are normally used in combination with a He/Cd laser, operating at for example 325 nm, an Argon-ion laser, operating for example at 351 nm, or 351 and 364 nm, or 333, 351, and 364 nm, or a frequency tripled Nd based solid state laser, having an output of 355 nm, as the radiation source, are acetophenones, such as 2,2-dialkoxybenzophenones and 1-hydroxyphenyl ketones, for example 1-hydroxycyclohexyl phenyl ketone, 2-hydroxy-1-{4-(2-hydroxyethoxy)phenyl}-2-methyl-1-propane, or 2-hydroxyisopropyl phenyl ketone (also called 2-hydroxy-2,2-dimethylacetophenone), but especially 1-hydroxycyclohexyl phenyl ketone. Another class of free-radical photoinitiators comprises the benzil ketals, such as, for example, benzil dimethyl ketal. Especially an alpha-hydroxyphenyl ketone, benzil dimethyl ketal, or 2,4,6-trimethylbenzoyldiphenylphosphine oxide is used as photo-initiator.

Another class of suitable free radical photoinitiators comprises the ionic dye-counter ion compounds, which are capable of absorbing actinic rays and producing free radicals, which can initiate the polymerization of the acrylates. The compositions according to the invention that comprise ionic dye-counter ion compounds can thus be cured in a more variable manner using visible light in an adjustable wavelength range of 400 to 700 nanometers. Ionic dye-counter ion compounds and their mode of action are known, for example from published European-patent application EP 223587 and U.S. Pat. Nos. 4,751,102; 4,772,530 and 4,772,541.

Especially preferred is the free-radical photoinitiator 1-hydroxycyclohexylphenyl ketone, which is commercially available as Irgacure 184.

The free-radical initiators constitute from about 0.01% to about 6% by weight, most preferably, from about 0.01% to about 3% by weight, of the total radiation curable composition.

(E) Optional Additives

If necessary, the resin composition for stereolithography applications according to the present invention may contain other materials in suitable amounts, as far as the effect of the present invention is not adversely affected. Examples of such materials include radical-polymerizable organic substances other than the aforementioned cationically polymerizable organic substances; heat-sensitive polymerization initiators, antifoaming agents, leveling agents, thickening agents, flame retardants and antioxidants. Optionally, hydroxyl-functional compounds may be added to dual-type SL resins.

The hydroxyl-functional compounds may be any organic material having a hydroxyl functionality of at least 1, and preferably at least 2. The material may be liquid or solid that is soluble or dispersible in the remaining components. The material should be substantially free of any groups which inhibit the curing reactions, or which are thermally or photolytically unstable.

Preferably, the hydroxyl-functional compounds are either aliphatic hydroxyl functional compounds or aromatic hydroxyl functional compounds.

The aliphatic hydroxyl functional compounds that may be useful for the present compositions include any aliphatic-type compounds that contain one or more reactive hydroxyl groups. Preferably these aliphatic hydroxyl functional compounds are multifunctional compounds (preferably with 2-5 hydroxyl functional groups) such as multifunctional alcohols, polyether-alcohols and polyesters.

Preferably the organic material contains two or more primary or secondary aliphatic hydroxyl groups. The hydroxyl group may be internal in the molecule or terminal. Monomers, oligomers or polymers can be used. The hydroxyl equivalent weight, i.e., the number average molecular weight divided by the number of hydroxyl groups, is preferably in the range of about 31 to 5000.

Representative examples of suitable organic materials having a hydroxyl functionality of 1 include alkanols, monoalkyl ethers of polyoxyalkyleneglycols, monoalkyl ethers of alkylene-glycols, and others.

Representative examples of useful monomeric polyhydroxy organic materials include alkylene glycols and polyols, such as 1,2,4-butanetriol; 1,2,6-hexanetriol; 1,2,3-heptanetriol; 2,6-dimethyl-1,2,6-hexanetriol; 1,2,3-hexanetriol; 1,2,3-butanetriol; 3-methyl-1,3,5-pentanetriol; 3,7,11,15-tetramethyl-1,2,3-hexadecanetriol; 2,2,4,4-tetramethyl-1,3-cyclobutanediol; 1,3-cyclopentanediol; trans-1,2-cyclooctanediol; 1,16-hexadecanediol; 1,3-propanediol; 1,4-butanediol; 1,5-pentanediol; 1,6-hexanediol; 1,7-heptanediol; 1,8-octanediol; 1,9-nonanediol; trimethylolpropane; and pentaerythritol.

Representative examples of useful oligomeric and polymeric hydroxyl-containing materials include polyoxyethylene and polyoxypropylene glycols and triols of molecular weights from about 200 to about 10,000; polytetramethylene glycols of varying molecular weight; copolymers containing pendant hydroxyl groups formed by hydrolysis or partial hydrolysis of vinyl acetate homo- and copolymers, polyvinylacetal resins containing pendant hydroxyl groups; hydroxyl-terminated polyesters and hydroxyl-terminated polylactones; hydroxyl-functionalized polyalkadienes, such as polybutadiene; and hydroxyl-terminated polyethers.

Other hydroxyl-containing monomers are 1,4-cyclohexanedimethanol and aliphatic and cycloaliphatic monohydroxy alkanols.

Other hydroxyl-containing oligomers and polymers include hydroxyl and hydroxyl/epoxy functionalized polybutadiene, polycaprolactone diols and triols, ethylene/butylene polyols, and combinations thereof. Examples of polyether polyols are also polypropylene glycols of various molecular weights and glycerol propoxylate-block-ethoxylate triol, as well as linear and branched polytetrahydrofuran polyether polyols available in various molecular weights, such as for example 250, 650, 1000, 2000, and 2900 MW.

Preferred hydroxyl functional compounds are for instance simple multifunctional alcohols, polyether-alcohols, and/or polyesters. Suitable examples of multifunctional alcohols are, trimethylolpropane; trimethylolethane; pentaeritritol; di-pentaeritritol; glycerol; 1,4-hexanediol; 1,4-hexanedimethanol and the like.

Suitable hydroxyfunctional polyetheralcohols are, for example, alkoxylated trimethylolpropane, in particular the ethoxylated or propoxylated compounds, polyethyleneglycol-200 or -600 and the like.

Suitable polyesters include, hydroxyfunctional polyesters from diacids and diols with optionally small amounts of higher functional acids or alcohols. Suitable diols are those described above. Suitable diacids are, for example, adipic acid; dimer acid; hexahydrophthalic acid; 1,4-cyclohexane dicarboxylic acid and the like. Other suitable ester compounds include caprolactone based oligo- and polyesters such as the trimethylolpropane-triester with caprolactone, Tone®301 and Tone310, both available from Union Carbide Chemical and Plastics Co. (UCCPC). The ester based polyols preferably have a hydroxyl number higher than about 50, in particular higher than about 100. The acid number preferably is lower than about 10, in particular lower than about 5. The most preferred aliphatic hydroxyl functional compound is trimethylolpropane, which is commercially available.

The aromatic hydroxyl functional compounds that may be useful for the present compositions include aromatic-type compounds that contain one or more reactive hydroxyl groups. Preferably these aromatic hydroxyl functional compounds would include phenolic compounds having at least 2 hydroxyl groups as well as phenolic compounds having at least 2 hydroxyl groups which are reacted with ethylene oxide, propylene oxide or a combination of ethylene oxide and propylene oxide.

The most preferred aromatic functional compounds include bisphenol A, bisphenol S, ethoxylated bisphenol A, ethoxylated bisphenol S.

These hydroxyl functional compounds are preferably present from about 3% to about 20% by weight, more preferably from about 5% to about 16% by weight, of the total liquid radiation-cured composition.

Two other preferred optional additives are pyrene and benzyldimethylamine. The former acts as a sensitizer and the latter acts as a stabilizer for the cationic polymerization. If used, optional additives such as these preferably constitute from about 0.001 to about 5% by weight of the total liquid radiation-curable compositions.

Examples of preferred liquid dual-type SL resins include AccuGen 100 ND, Accura Si10 ND and RPCure 400 ND, all available commercially from 3D Systems, Inc. of Valencia, Calif.

An example of a liquid radical-curable SL resin is RPCure 550 ND, also available from 3D Systems, Inc.

Soluble Dye Compounds

The selected soluble dye compounds used in the radiation-curable compositions of the present invention are members of the classes of diarylmethane and triarylmethane dyes, rhodamine dyes, azo dyes, thiazole dyes, anthraquinone dyes and safranine dyes that do not substantially lower the photospeed characteristics of SL resin systems being used and do not bleach out during photoexposure (e.g. during laser exposure). Not all members of these five (5) classes of liquid dyes pass these additional characteristics (see Comparative Examples below). These dyes are added in effective color-imparting amounts, preferably in amounts from about 0.001 to about 0.1 percent by weight of the total radiation-curable composition to impart a sufficient amount of color to the cured composition. Preferred are dyes containing amino,-hydroxyl-carboxyl- or (meth)acrylate groups that are covalently bound to the network prior to or upon irradiation. The preferred dyes are Crystal Violet, Rhodamin B, Coomassie Brilliant Blue R, Basic Red 9, Disperse Orange 11, Disperse Red 19, Thioflavine T, Auramine O and Safranine O. These dyes do not affect the photospeed of the SL composition, as almost identical working curves are obtained before and after the addition of the dye. A viscosity stabilizing effect is observed for dual cure systems with dyes containing amino groups. An effective color-imparting amount is obtained when good color contrasts or sufficient color saturation is present to improve magnified viewing of parts or to impart the desired visual and aesthetic effect.

Formulation Preparation

The novel compositions can be prepared in a known manner by, for example, premixing individual components and then mixing these premixes, or by mixing all of the components using customary devices, such as stirred vessels, in the absence of light and, if desired, at slightly elevated temperature.

One preferred mixing method is to premix ingredients (A), (B), (C), (D) and optionally (E) as forming a regular dual-type stereolithographic resin composition. The previously made mixture of ingredients (A), (B), (C), (D) and optionally (E) are then combined to the liquid dye compound or compounds. These ingredients are thoroughly mixed in a suitable mixer or mixers for a sufficient amount of time.

Process of Making Cured Three-Dimensional Articles

The above-noted novel compositions can be polymerized by irradiation with actinic light, for example by means of electron beams, X-rays, UV or VIS light, preferably with radiation in the wavelength range of about 280 to about 650 nm. Particularly suitable are laser beams of HeCd, argon or nitrogen, semiconductor and also metal vapor and Nd:YAG or other Nd based solid state lasers with frequency multiplication. This invention is extended throughout the various types of lasers existing or under development that are to be used for the stereolithography process, e.g., solid state, argon ion, helium cadmium lasers, and the like. The person skilled in the art is aware that it is necessary, for each chosen light source, to select the appropriate photoinitiator and, if appropriate, to carry out sensitization. It has been recognized that the depth of penetration of the radiation into the composition to be polymerized, and also the operating rate, are inversely proportional to the absorption coefficient and to the concentration of the photoinitiator. In stereolithography it is preferred to employ those photoinitiators which give rise to the highest number of forming free radicals or cationic particles and have a high absorption coefficient at the operating wavelength.

The invention additionally relates to a method of producing a cured product, in which compositions as described above are treated with actinic radiation. For example, it is possible in this context to use the novel compositions as adhesives, as coating compositions, as photoresists, for example as solder resists, or for rapid prototyping, but especially for stereolithography. When the novel mixtures are employed as coating compositions, the resulting coatings on wood, paper, metal, ceramic or other surfaces are clear and hard. The coating thickness may vary greatly and can, for instance, be from 0.01 mm to about 1 mm. Using the novel mixtures it is possible to produce relief images for printed circuits or printing plates directly by irradiation of the mixtures, for example by means of a computer-controlled laser beam of appropriate wavelength or employing a photomask and an appropriate light source.

One specific embodiment of the above mentioned method is a process for the stereolithographic production of a three-dimensional shaped article, in which the article is built up from a novel composition with the aid of a repeating, alternating sequence of steps (a) and (b); in step (a), a layer of the composition, one boundary of which is the surface of the composition, is cured with the aid of appropriate radiation within a surface region which corresponds to the desired cross-sectional area of the three-dimensional article to be formed, at the height of this layer, and in step (b) the freshly cured layer is covered with a new layer of the liquid, radiation-curable composition, this sequence of steps (a) and (b) being repeated until an article having the desired shape is formed. In this process, the radiation source used is preferably a laser beam, which with particular preference is computer-controlled.

In general, the above-described initial radiation curing, in the course of which the so-called green models are obtained which do not as yet exhibit adequate strength, is followed then by the final curing of the shaped articles by heating and/or further irradiation.

The present invention is further described in detail by means of the following Examples and Comparisons. All parts and percentages are by weight and all temperatures are degrees Celsius unless explicitly stated otherwise.

### EXAMPLES

The tradenames of the components as indicated in the Examples below correspond to the chemical substances in the following Table 1:

TABLE 1

| Trade Name | Chemical Designation |
|---|---|
| AccuGen 100 ND | dual-type stereolithographic resin available |
| | commercially from 3D Systems, Inc. |
| Accura Si10 ND | dual-type stereolithographic resin available |
| | commercially from 3D Systems, Inc. |
| RPCure 400 ND | dual-type stereolithographic resin available |
| | commercially from 3D Systems |
| RPCure 550 ND | acrylate-based or radical-curable |
| | stereolithographic resin available |
| | from 3D Systems |
| Crystal Violet | Blue colored triarylmethane soluble dye |
| Rhodamin B | Pink colored rhodamine soluble dye |
| Coomassie Brilliant Blue | Blue colored triarylmethane soluble dye |
| Basic Red 9 | Red colored triarylmethane soluble dye |
| Disperse Orange 11 | Orange colored anthraquinone dye |
| Disperse Red 19 | Red colored triarylmethane soluble dye |
| Thioflavine T | Yellow colored thiarole soluble dye |
| Safranine O | Red colored safranine soluble dye |
| Auramine O | Yellow colored soluble diarylmethane dye |
| Erioglaucine | Greenish blue soluble triarylmethane dye |

Protocol for Testing

The photosensitivity of the liquid formulations was determined on so-called window panes. In this determination, single-layer test specimens were produced using different laser energies, and the layer thicknesses obtained were measured. The plotting of the resulting layer thickness on a graph against the logarithm of the irradiation energy used gave a “working curve.” The slope of this curve is termed Dp (given in mm or mils). The energy value at which the curve passes through the x-axis is termed Ec (and is the energy at which gelling of the material still just takes place; cf. P. Jacobs, Rapid Prototyping and Manufacturing, Soc. of Manufacturing Engineers, 1991, p. 270 ff.).

Color stability for postcure exposure:

The colored resin formulations noted below were tested for color stability by evaluating their main absorption band in the visible spectrum (400-750 nm range) after a brief exposure (2 min. under a 125 W Hg lamp) and 1 hour in the center of a 3D Systems, Inc. PCA unit with 10 fluorescent UV tubes (or another 15 min. under the 125 W Hg lamp, as mentioned in each example). The spectroscopy samples were prepared as thin films of 0.25 mm sandwiched between 2 microscope slides with appropriate spacers. The absorption maxima were compared before and after UV-curing and color stability was determined sufficient if the decrease of absorption was less than 30%.

### Formulation Example 1

100 g AccuGen™ 100 ND resin and 0.01 g Crystal Violet [CAS No. 548-62-9] (dye class: triarylmethane) were heated under stirring to 60° for 2 hours. A homogeneous, dark blue solution was obtained. Photosensitivity measurements (window-panes) give Dp=3.88 and Ec=7.67. The change in absorption before and after curing (bleaching out) was less than about 30%.

### Formulation Example 2

100 g AccuGen™ 100 ND resin and 0.025 g Rhodamin B [CAS No. 81-88-9] (dye class: rhodamine) were heated under stirring to 60° for 2 hours. A homogeneous, pink, fluorescing solution was obtained. Photosensitivity measurements (window-panes) give Dp=4.1 and Ec=12.1. No color change was detected after UV curing of the composition.

### Formulation Example 3

100 g Accura® si 10 ND resin and 0.015 g Coomassie Brilliant Blue R 250 [CAS No. 6104-59-2] (dye class: triarylmethane) were heated under stirring to 60° for 2 hours. A homogeneous, dark blue solution was obtained. Photosensitivity measurements (window-panes) give Dp=5.4 and Ec=17.7. Stability: peak@ 593 nm before exposure to 3D Systems' PCA unit 0.252 absorption units (AU,) after 1 hour exposure to 3D Systems' PCA unit 0.238 AU (−8%).

### Formulation Example 4

99.4 g Accura® si 10 ND resin, 0.6 g pyrene and 0.005 g Crystal Violet [CAS No. 548-62-9] were heated under stirring to 60° for 2 hours. A homogeneous, dark blue solution was obtained. Photosensitivity measurements (window-panes) give Dp=2.3 and Ec=14.2. Stability: peak@ 597 nm before exposure to Hg lamp/25 cm: 0.177 AU, after 15′ exposure to Hg lamp/25 cm: 0.123 AU (−30%).

### Formulation Example 5

99.8 g RPCure 400 ND resin, 0.2 g pyrene and 0.015 g Basic Red 9[[CAS no. 569-61-9] (dye class: triarylmethane) were heated under stirring to 60° for 2 hours and then over night at 40° C. A homogeneous, dark purple solution was obtained. Photosensitivity measurements (window-panes) give DP=3.3, and Ec=15.5. The absorption change after curing was less than about 20%.

### Formulation Example 6

99.4g Accura® si 10 ND resin, 0.6 g pyrene and 0.015 g Basic Red 9[CAS No. 569-61-9] (dye class: triarylmethane) were heated under stirring to 60° for 2 hours and then over night at 40° C. A homogeneous, dark purple solution was obtained. Photosensitivity measurements (windowpanes) give Dp=2.76 and Ec=16.34. Stability: peak@ 560 nm before exposure 0.823 AU, after 1 hour exposure to Hg lamp 0.664 AU (−19%) (shifted to higher wavelength).

### Formulation Example 7

100 g RPCure 400 ND resin, 0.2 g pyrene and 0.01 g Crystal Violet [CAS No. 548-62-9] were heated under stirring to 60° for 2 hours. A homogeneous, dark blue solution was obtained. Photosensitivity measurements (window-panes) give Dp=3 and Ec=11.5. The absorption change (bleaching out) after curing was less than about 30%.

### Formulation Example 8

100 g RPCure 550 ND resin (an acrylate- based SL resin) and 0.015 g Crystal Violet [CAS No. 548-62-9] were heated under stirring to 60° for 2 hours. A homogeneous, dark blue solution was obtained. Photosensitivity measurements (window-panes) give Dp=4.4 and Ec=8.8. The absorption change (bleaching out) after curing was less than about 30%.

### Formulation Example 9

400 g Accura® si 10 resin without Amine-Stabilizer and 0.06 g Basic Red 9 [CAS No. 569-61-9] (dye class: triarylmethane, containing amino groups) were heated under stirring at 60° for 1 hour. A dark purple solution was obtained. The highly stable colored resin did not gel when maintained at 110° C. for more than 21 hours.

### Formulation Example 10

200 g AccuGen™ 100 ND resin and 0.04 g Disperse Red 19[CAS No. 2734-52-3](dye class: Azo) were heated at 60° under stirring for 1 hour. A red solution was obtained. Photosensitivity measurements give Dp=4.3 and Ec=12.7. The absorption change (bleaching out) curing was less than about 20%.

### Formulation Example 11

200 g Accura™ si 10 resin and 0.03 g Thioflavine T [CAS No. 2390-54-7] (dye class: Thiazole) were heated at 60° under stirring for 1 hour. A clear and brilliant yellow solution was obtained. Photosensitivity was determined to give Dp=5.2 and Ec−12.5. No color change was detected after UV-curing.

### Formulation Example 12

200 g Accura® si 10 resin and 0.02 g Safranine O [CAS No. 477-73-6 (dye class: Safranine) were heated at 60°0 under stirring for 1 hour. A bright orange solution was obtained. The absorption change after curing was less than 20%.

### Application Example 13

A part was built with the resin from Example 4 on a Viper si2™ SLA® system, using the high resolution mode with 0.05 mm layer thickness. A blue part was obtained with a peak absorption at 597 nm. After post-curing in a PCA unit for 1 hour, there was a slight decrease in color intensity.

### Application Example 14

A part was built with the resin from Example 6 on a Viper si2™ SLA™ system, using the high resolution mode with 0.05 mm layer thickness. A dark purple part was obtained with a peak absorption at 560 nm. After post-curing in a PCA unit for 1 hour, there was a very slight shift in color toward red. The colored part was immersed in acetone and stirred for 6 hours. No coloration of the acetone solution and no decoloration of the outside of the part was observed.

### Application Example 15

A rectangular plate of 10×20×1.5 mm was built with the resin from Example 4 on a Viper si2™ SLA™ system, using the high resolution mode with 0.05 mm layer thickness. A blue part was obtained with a peak absorption of 0.91 A.U. at 597 nm. After post-curing in front of a 125 W mercury lamp for 1 hour at a distance of 25 cm, the absorption changed to 0.83 A.U.

### Comparative Example 1

200 g Accura® si 10 ND resin and 0.03 g Meldola's Blue [CAS No. 7057-57-0] (dye class: Oxazin) were heated at 60° under stirring for 1 hour. A blue solution was obtained. After several hours this solution bleached out completely and became colorless. Solidification of this uncolored solution by UV exposure gives colorless parts.

Comparative Examples 2-5

Colored solutions were obtained using the same procedures as described in the above examples 1 to 11 with the following dyes:

Eosin Scarlet [CAS No. 548-24-3] (dye class: Fluorone)

Eriochrome Cyanine [CAS No. 3564-18-9] (dye class: Triarylmethane)

Basic Blue 41 [CAS No. 12270-13-2] (dye class: Thiazole)

Acid Alizarin Violet [CAS No. 2092-55-9] (dye class: Azo)

During exposure of these solutions to UV light, the colors disappeared completely and only colorless parts could be obtained. These liquid dye compounds are not useful for the present invention.

While the invention has been described above with reference to specific embodiments thereof, it is apparent that many changes, modifications, and variations can be made without departing from the inventive concept disclosed herein. Accordingly, it is intended to embrace all such changes, modifications and variations that fall within the spirit and broad scope of the appended claims. All patent applications, patents and other publications cited herein are incorporated by reference in their entirety.

What is claimed is:

1. A liquid colored radiation-curable composition useful for the production of three dimensional articles by stereolithography comprising a substantially homogeneous admixture of (1) a liquid uncolored radical-curable or dual-type stereolithographic resin system and (2) an effective color-imparting amount of at least one soluble dye compound selected from the group consisting of diarylmethane and triarylmethane dyes, rhodamine dyes, azo dyes, thiazole dyes, anthraquinone dyes and safranine dyes; said liquid colored radiation curable composition having substantially the same photospeed as the uncolored resin system and the absorption of color imparted by the liquid dye compound decreases less than about 30% during radiation exposure.

2. A liquid colored radiation-curable composition useful for the production of three dimensional articles by stereolithography that comprises
(A) at least one cationically polymerizing organic substance;
(B) at least one free-radical polymerizing organic substance;
(C) at least one cationic polymerization initiator;
(D) at least one free-radical polymerization initiator; and
(E) an effective color-imparting amount of at least one soluble dye compound selected from the group consisting of diarylmethane and triarylmethane dyes, rhodamine dyes, azo dyes, thiazole dyes, anthraquinone dyes and safranine dyes; said liquid colored radiation-curable composition having substantially the same photospeed as the composition without dye component (E) and the absorption of color imparted by the soluble dye compound decreases less than about 30% during radiation exposure.

3. The composition of claim 2 wherein component (A) is at least aliphatic, alicyclic or aromatic polyglycidyl compound or cyclopolyepoxide or epoxy cresol novolac or epoxy phenol novolac compound.

4. The composition of claim 2 wherein component (A) comprises a mixture of (1) at least one alicyclic epoxide having at least two epoxy groups; and (2) at least one difunctional or higher functional glycidylether of a polyhydric compound.

5. The composition of claim 4 wherein component (A)(1) is 3,4-epoxycyclohexylmethyl-3′,4′-epoxycyclohexane carboxylate.

6. The composition of claim 2 wherein component (A)(2) is trimethylol propane triglycidylether.

7. The composition of claim 2 wherein the component (A) constitutes about 30% to about 80% by weight of the total radiation-curable composition.

8. The composition of claim 2 wherein component B is at least one solid or liquid poly(meth) acrylate.

9. The composition of claim 2 wherein component B comprises a mixture of (1) at least one trifunctional or higher functional (meth) acrylate compound and (2) optionally at least one aromatic di(meth) acrylate compound

10. The composition of claim 9 wherein component (B)(1) is a tri-, tetra or pentafunctional monomeric or oligomeric aliphatic, cycloaliphatic, or aromatic (meth)acrylate.

11. The composition of claim 10 wherein component (B)(1) is dipentaerythritol monohydroxy-pentaacrylate.

12. The composition of claim 9 wherein component (B)(2) is present and is a di(meth)acrylate of an aromatic diol.

13. The composition of claim 12 wherein the di(meth)acrylate of an aromatic diol is bisphenol A diglycidylether diacrylate.

14. The composition of claim 2 wherein component (B) constitutes from about 1% to about 20% by weight of the total liquid radiation-curable composition.

15. The composition of claim 2 wherein component (C) is triarylsulfonium hexafluoroantimonate.

16. The composition of claim 2 wherein component (C) constitutes from about 0.01 to about 10% by weight of the total liquid radiation-curable composition.

17. The composition of claim 2 wherein component (D) is 1-hydroxycyclohexyl phenyl ketone.

18. The composition of claim 2 wherein component (D) constitutes from about 0.01 to about 6% by weight of the total liquid radiation-curable composition.

19. The composition of claim 2 wherein component E is a dye selected from the groups described in claim 2 and contains amino, hydroxyl, carboxyl- or (meth)acrylate groups.

20. The composition of claim 2 wherein component (E) is a diarylmethane or triarylmethane dye.

21. The composition of claim 2 wherein component (E) is a rhodamine dye.

22. The composition of claim 2 wherein component (E) is Coumassie Brilliant Blue, Rhodamin B, Basic Red 9or Auramine O.

23. The composition of claim 2 wherein component (E) constitutes from about 0.001% to about 0.1% by weight of the total liquid radiation-cured composition.

24. The composition of claim 2 wherein the radiation-curable additive contains a hydroxyl functional compound.

25. The composition of claim 2 wherein the radiation-curable composition additionally contains pyrene.

26. A liquid radiation-curable composition useful for the production of three dimensional articles by stereolithography that comprises
(A) at least one cationically polymerizing organic substance;
(B) at least one free-radical polymerizing organic substance;
(C) at least one cationic polymerization initiator;
(D) at least one free radical polymerization initiator; and
(E) an effective color-imparting amount of at least one soluble dye selected from the group consisting of Coumassie Brilliant Blue, Rhodamin B and Basic Red 9.

27. A process for forming a three-dimensional article, said process comprising the steps:
(1) coating a thin layer of a composition onto a surface;
(2) exposing said thin layer imagewise to actinic radiation to form an imaged cross-section, wherein the radiation is of sufficient intensity to cause substantial curing of the thin layer in the exposed areas;
(3) coating a thin layer of the composition onto the previously exposed imaged cross-section;
(4) exposing said thin layer from step (3) imagewise to actinic radiation to form an additional imaged cross-section, wherein the radiation is of sufficient intensity to cause substantial curing of the thin layer in the exposed areas and to cause adhesion to the previously exposed imaged cross-section;
(5) repeating steps (3) and (4) a sufficient number of times in order to build up the three-dimensional article;
wherein the composition is that which is described in claim 2.
